(19) United States
(12) Patent Application Publication
(10) Pub. No.: US 2014/0048496 A1
(43) Pub. Date: Feb. 20, 2014

(54) MOUNTING APPARATUS FOR ELECTRONIC DEVICE

(71) Applicants: HON HAI PRECISION INDUSTRY CO., LTD., New Taipei (TW); HONG FU JIN PRECISION INDUSTRY (WuHan) CO., LTD., Wuhan (CN)

(72) Inventors: YUN-LUNG CHEN, New Taipei (TW); CHUNG CHAI, New Taipei (TW); DA-LONG SUN, Wuhan (CN); YU-GUI CHEN, Wuhan (CN); NIAN-YUAN YANG, Wuhan (CN)

(73) Assignees: HON HAI PRECISION INDUSTRY CO., LTD., New Taipei (TW); HONG FU JIN PRECISION INDUSTRY (WUHAN) CO., LTD., Wuhan (CN)

(21) Appl. No.: 13/902,269

(22) Filed: May 24, 2013

(30) Foreign Application Priority Data
Aug. 16, 2012 (CN) 2012102915909

(51) Int. Cl. H05K 7/18

(52) U.S. Cl. CPC H05K 7/18
USPC 211/26

(57) ABSTRACT

A mounting apparatus for electronic device includes a rack, a blocking member and a knob. The rack includes a bottom plate, a first side plate and a second side plate extending from opposite sides of the bottom plate. The bottom plate, the first side plate and the second side plate are configured to cooperatively clip an electronic device. The blocking member is rotatably secured to the first side plate and configured to prevent the electronic device from sliding along a first direction parallel to the first side plate and the bottom plate, to disengage from the rack. The knob is attached to the second side plate and engaged with the blocking member, for preventing the blocking member from being rotated relative to the first side plate.

### BACKGROUND

1. Technical Field

The present disclosure relates to mounting apparatus, and particularly to a mounting apparatus for a computer host of a vending machine.

2. Description of Related Art

Vending machine always includes a computer host for data storage. The computer host is generally mounted in a rack of the vending machine by screws which require setting tools. Thus, traditional install procedure of the computer host is tedious and inconvenient.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an embodiment of a mounting apparatus and an electronic device.

FIG. 2 is an exploded, isometric view of a rack of FIG. 1.

FIG. 3 is an exploded view of a knob of FIG. 1.

FIG. 4 is an exploded view of a blocking member of FIG. 1.

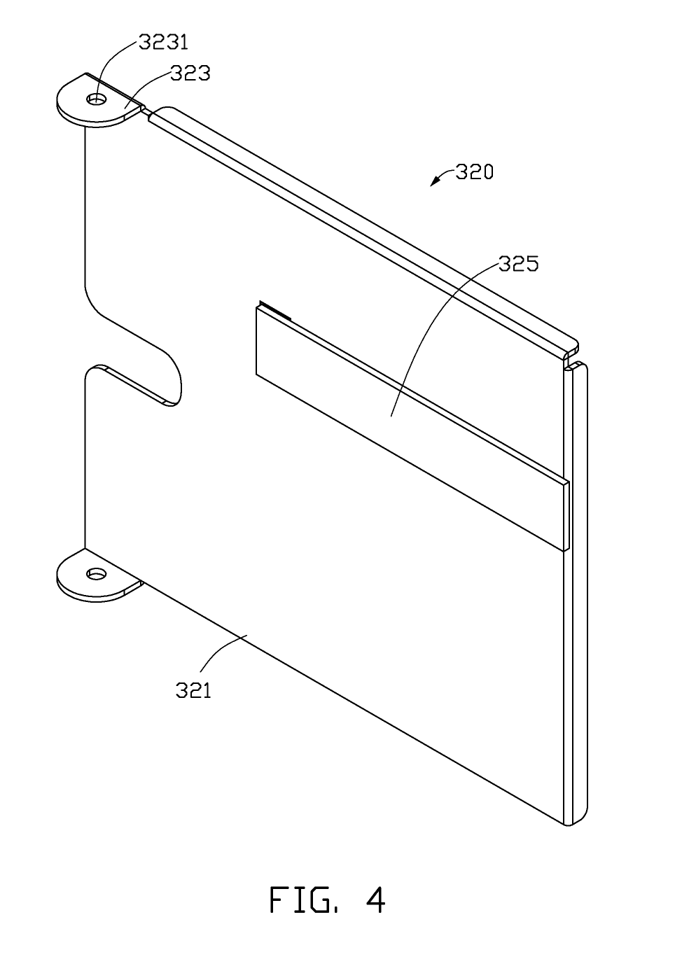

FIG. 5 is an assembled view of the mounting apparatus and the electronic device of FIG. 1.

FIG. 6 is similar to FIG. 5, but viewed from a different aspect.

FIG. 7 is similar to FIG. 5, but viewed from another different aspect.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

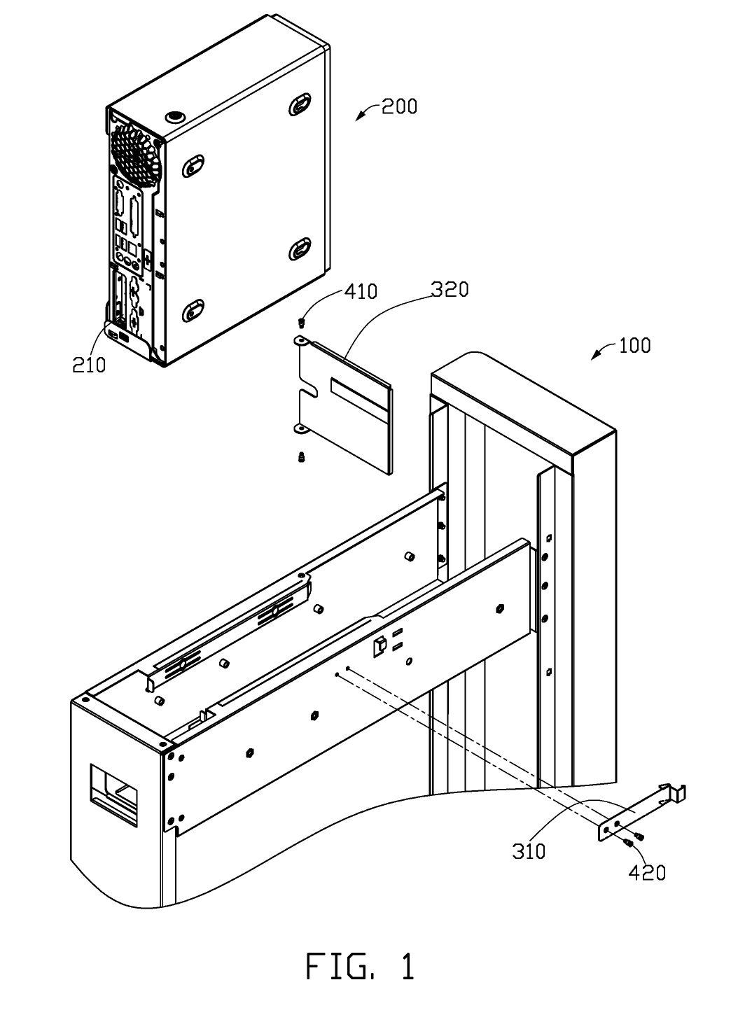

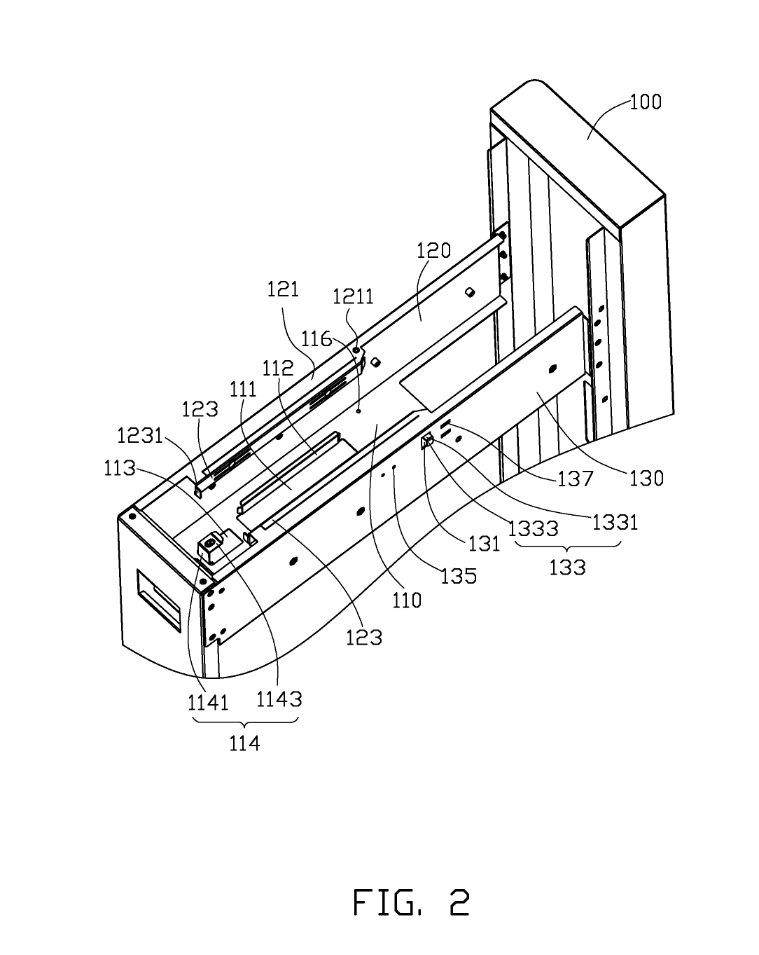

FIGS. 1-2 illustrate a mounting apparatus in accordance with an embodiment. The mounting apparatus is configured to secure an electronic device 200. The mounting apparatus includes a rack 100, a knob 310 attached to the rack 100 and a blocking member 320 rotatably secured to the rack 100. The electronic device 200 may be a computer host, for example. A positioning slot 210 is defined in one side of the electronic device 200.

The rack 100 includes a bottom plate 110, a first side plate 120 and a second side plate 130. The first side plate 120 and the second side plate 130 extend from two opposite sides of the bottom plate 110. In one embodiment, the first side plate 120 and the second side plate 130 are substantially parallel to each other and perpendicular to the bottom plate 110.

The bottom plate 110 defines a heat dissipating opening 111. Two clamping pieces 112 extend upwards from opposite edges of the heat dissipating opening 111. The two clamping pieces 112 are substantially parallel to each other and perpendicular to the bottom plate 110. The two clamping pieces 112 are parallel to the first side plate 120 and the second side plate 130. A first distance between the two clamping pieces 112 is substantially equal to a width of the electronic device 200. An aperture 113 is defined in the bottom plate 110, positioning on one side of the opening 111. A first rotating hole 116 is defined in the bottom plate 110, positioned on another side of the opening 111. A restricting portion 114 is located on the bottom plate 110 and includes a restricting tab 1141 and a pressing tab 1143. The restricting tab 1141 extends upwards from one edge of the aperture 113, and the pressing tab 1143 extends horizontally from the restricting tab 1141, parallel to the bottom plate 110.

A first flange 121 extends inwards from a top edge of each of the first side plate 120 and the second side plate 130. A second flange 123 extends downwards from a distal end of the first flange 121. A second distance between the second flanges 123 is substantially equal to the width of the electronic device 200. A stopping tab 1231 extends inwards from each second flange 123. A second rotating hole 1211 is defined in one corner of the first flange 121, corresponding to the first rotating hole 116. The first rotating hole 116 is defined in a line with the second rotating hole 1211. The line is substantially perpendicular to the bottom plate 110.

The second side plate 130 defines a small opening 131. A limiting portion 133 is located on the second side plate 130 and includes a connecting tab 1331 and a limiting tab 1333. The connecting tab 1331 extends outwards from a top edge of the small opening 131. The limiting tab 1333 extends downwards from a distal end of the connecting tab 1331. Two mounting holes 135 and two through holes 137 are defined in the second side plate 130, locating on opposite sides of the small opening 131.

FIG. 2 shows that the knob 310 includes a resilient piece 313 and an actuating portion 311. The resilient piece 313 is substantially rectangular. A first end of the resilient piece 313 defines two securing holes 3131 that correspond to the two mounting holes 135. Two latch tabs 3133 extend from opposite edges of a second end of the resilient piece 313 that correspond to the two through holes 137. The actuating portion 311 extends from the second end of the resilient piece 313.

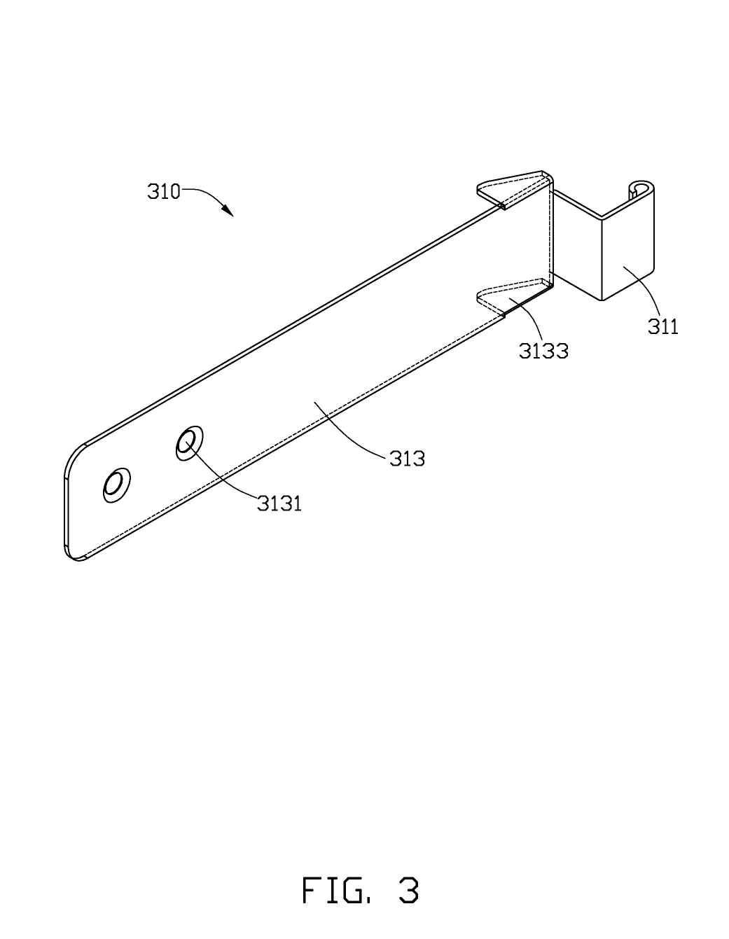

FIG. 3 shows that the blocking member 320 includes a blocking plate 321. The blocking plate 321 is substantially rectangular. Two pivot tabs 323 extend from opposite edges of one end of the blocking plate 321. A pivot hole 3231 is defined in each of the two pivot tabs 323, corresponding to the first rotating hole 116, the second rotating hole 1211. A shake absorbing gasket 325 is attached to the blocking plate 321.

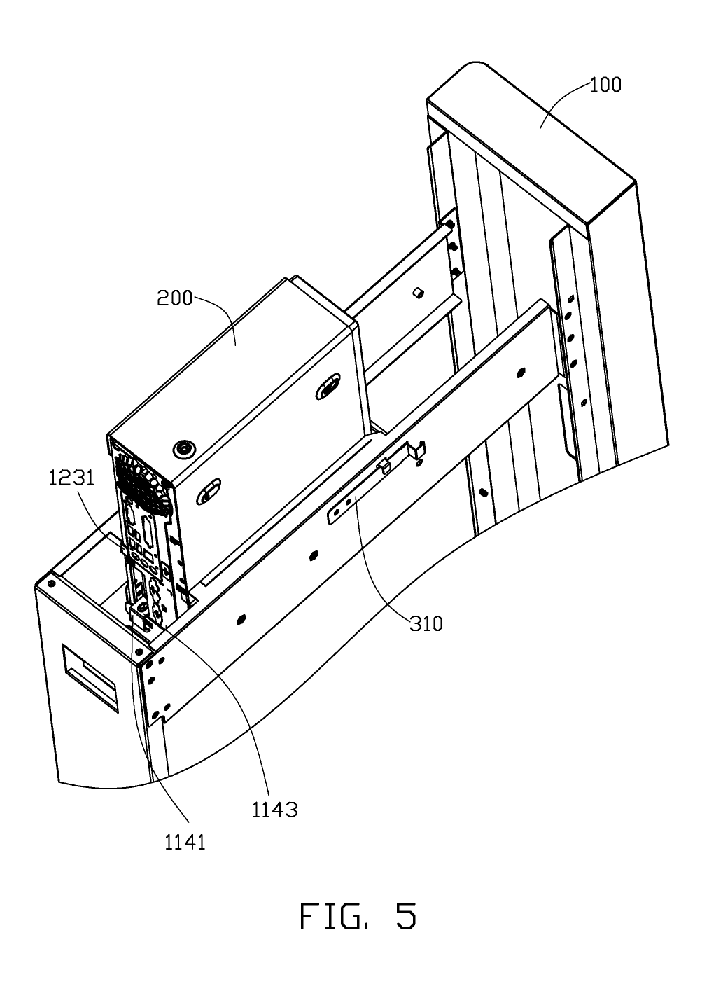

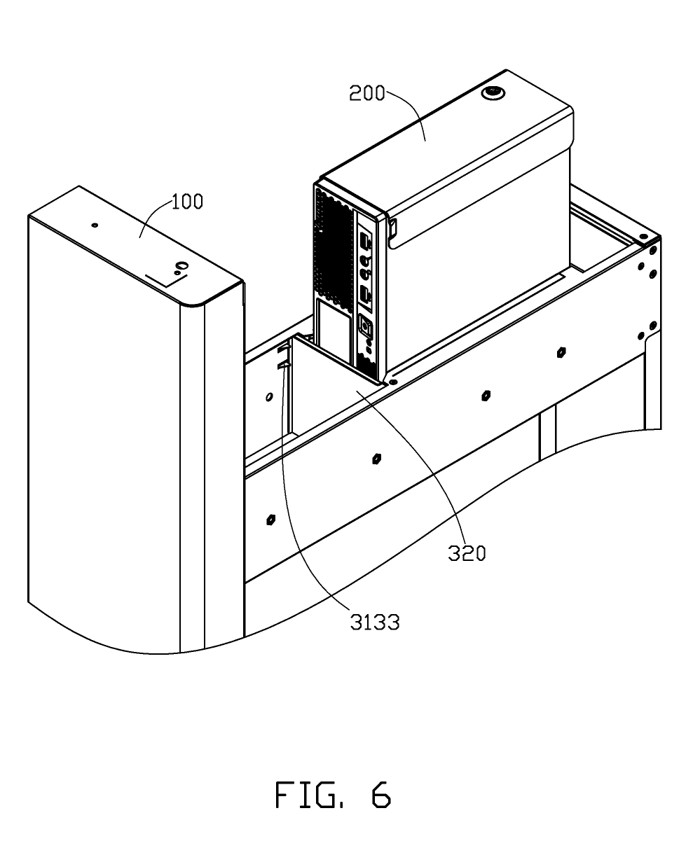

FIGS. 5-6 illustrate that, in assembly in one embodiment, the electronic device 200 is placed on the bottom plate 110 between the two clamping pieces 112, and then it is pushed to move towards the restricting portion 114, until the restricting tab 1141 abuts a bottom portion of a back side of the electronic device 200. The pressing tab 1143 is inserted into the positioning slot 210. Each stopping tab 1231 abuts a top portion of the back side of the electronic device 200.

The blocking member 320 is positioned on the bottom plate 110, and each pivot hole 3231 is aligned with each of the first rotating hole 116 and the second rotating hole 1211. Two locking members 410 are locked into each pivot hole 3231 as well as the first rotating hole 116, and the second rotating hole 1211, to secure the blocking member 320 to the rack 100. The shake absorbing gasket 325 abuts a front side of the electronic device 200, to prevent the electronic device 200 from sliding along a first direction parallel to the bottom plate 110 and the first side plate 120.

The two securing holes 3131 of the knob 310 are aligned with the two mounting holes 135 of the second side plate 130, and two fasteners 420 are locked into the two securing holes 3131 and the two mounting holes 135, to secure the knob 310 to the second side plate 130. The two latch tabs 3133 extend through the two through holes 137. The blocking plate 321 of the blocking member 320 is thereby located in a first position, where the blocking plate 321 is engaged with the two latch tabs 3133, to prevent the blocking plate 321 from being rotated relative to the first side plate 120, and substantially perpendicular to the second side plate 130. In this position, each stopping tab 1231 and the restricting tab 1141 prevents the electronic device 200 from moving along a second direction opposite to the first direction. The pressing tab of the restricting portion 114 prevents the electronic device 200 from moving along a third direction substantially perpendicular to the first direction and the second direction. The electronic device 200 is thereby secured to the rack 100.

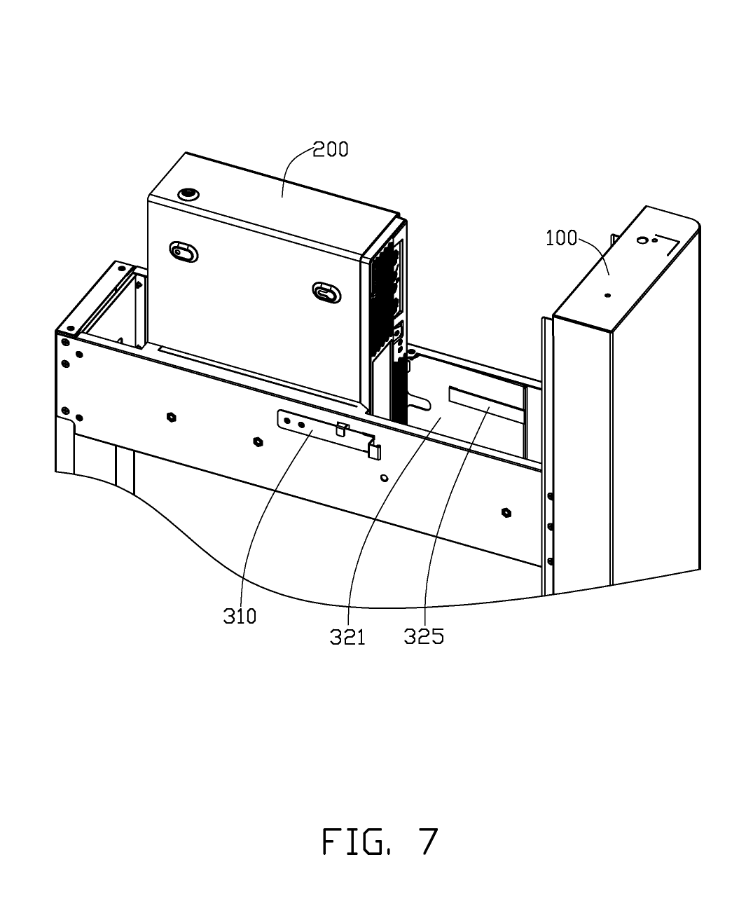

FIG. 7 show that in disassembly, the actuating portion 311 is operated to be resiliently deformed the resilient piece 313, to disengage the two latch tabs 3133 from the blocking plate 321. The blocking plate 321 is rotated around the two pivot tabs 323 to a second position to disengage from the electronic device 200 and the two latch tabs 3133. The electronic device 200 is pushed to move away from the restricting portion 114, and then easily detached from the rack 100. The limiting tab 1333 of the limiting portion 133 abuts the resilient piece 313 when the resilient piece 313 is deformed, to prevent the resilient piece 313 from being over-deformed.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. A mounting apparatus for electronic device comprising:
a rack comprising a bottom plate, a first side plate and a second side plate extending from opposite sides of the bottom plate, and the bottom plate; the first side plate and the second side plate configured to cooperatively receive the electronic device;
a blocking member is rotatably secured to the first side plate and configured to prevent the electronic device from sliding along a first direction, that is parallel to the first side plate and the bottom plate; and
a knob attached to the second side plate and engaged with the blocking member, for preventing the blocking member from being rotated away from the first side plate.

2. The mounting apparatus of claim 1, wherein the knob comprises a resilient piece, a first end of the resilient piece is secured to the second side plate, two latch tabs extend from a second end of the resilient piece, the second side plate defines two through holes, and the two latch tabs extend through the two through holes to engage with the blocking member.

3. The mounting apparatus of claim 2, wherein the knob further comprises an actuating portion extending from the resilient piece and adjacent to the two latch tabs, and the resilient piece is resiliently deformable to disengage the two latch tabs from the blocking member driven by the actuating portion.

4. The mounting apparatus of claim 3, wherein a limiting portion is located on the second side plate, adjacent to the two through holes; the limiting portion comprises a connecting tab, extending from the second side plate, and a limiting tab, perpendicularly extending from the connecting tab; and the limiting tab abuts the resilient piece, when the resilient piece is resiliently deformed, for preventing the resilient piece from being over-deformed.

5. The mounting apparatus of claim 1, wherein the blocking member comprises a blocking plate, and the blocking plate is rotatable between a first position and a second position relative to the first side plate; in the first position, the blocking plate is engaged with the knob and substantially perpendicular to the first side plate; and in the second position, the blocking plate is disengaged from the knob.

6. The mounting apparatus of claim 5, wherein the blocking member comprises two pivot tabs located on the blocking plate, one of the two pivot tabs is rotatably secured to the bottom plate, and another one of the two pivot tabs is rotatably secured to the first side plate, to secure the blocking member to the first side plate.

7. The mounting apparatus of claim 5, wherein an absorbing shake gasket is located on the blocking plate, and the absorbing shake gasket is configured to abut the electronic device when the blocking plate is in the first position.

8. The mounting apparatus of claim 1, wherein a flange extends from each of the first side plate and the second side plate, two stopping tabs extend towards each other from each flange, and the two stopping tabs are configured to abut the electronic device, for preventing the electronic device from sliding along a second direction opposite to the first direction.

9. The mounting apparatus of claim 8, wherein a restricting portion is located on the bottom plate and opposite to the blocking member, and the restricting portion is configured to engage with the electronic device.

10. The mounting apparatus of claim 9, wherein the restricting portion comprises a restricting tab, extending from the bottom plate, and a pressing tab, perpendicularly extending from the restricting tab; the restricting tab is configured to prevent the electronic device from sliding along the second direction; and the pressing tab is configured to abut the electronic device, for preventing the electronic device from moving along a third direction perpendicular to the bottom plate.

11. A mounting apparatus for electronic device comprising:
a rack configured to receive an electronic device;
a blocking member rotatably secured to the rack, to prevent the electronic device from disengaging from the rack; and
a knob attached to the rack engaged with the blocking member, for preventing the blocking member from rotating relative to the rack.

12. The mounting apparatus of claim 11, wherein the rack comprises a bottom plate, a first side plate and a second side plate extending from opposite sides of the bottom plate, and the bottom plate, the first side plate and the second side plate is configured to cooperatively clip an electronic device.

13. The mounting apparatus of claim 12, wherein the blocking member comprises a blocking plate, the blocking plate is rotatable between a first position and a second position relative to the first side plate; in the first position, the blocking plate is engaged with the knob and substantially perpendicular to the first side plate, to prevent the electronic device from sliding along a first direction parallel to the bottom plate and the first side plate; and in the second position, the blocking plate is disengaged from the knob.

14. The mounting apparatus of claim 13, wherein the blocking member comprises two pivot tabs located on the blocking plate, one of the two pivot tabs is rotatably secured to the bottom plate, and another one of the two pivot tabs is rotatably secured to the first side plate, to secure the blocking member to the rack.

15. The mounting apparatus of claim 12, wherein the knob comprises a resilient piece; a first end of the resilient piece is secured to the second side plate, two latch tabs extend from a second end of the resilient piece, the second side plate defines two through holes; and the two latch tabs extends through the two through holes to engage with the blocking member.

16. The mounting apparatus of claim 15, wherein the knob further comprises an actuating portion extending from the resilient piece and adjacent to the two latch tabs, and the resilient piece is resiliently deformable to disengage the two latch tabs from the blocking member driven by the actuating portion.

17. The mounting apparatus of claim 16, wherein a limiting portion is located on the second side plate and adjacent to the two through holes, the limiting portion comprises a connecting tab extending from the second side plate and a limiting tab perpendicularly extending from the connecting tab, and the limiting tab abuts the resilient piece when the resilient piece is resiliently deformed, for preventing the resilient piece from being over-deformed.

18. The mounting apparatus of claim 14, wherein an absorbing shake gasket is located on the blocking plate, and the absorbing shake is configured to abut the electronic device when the blocking plate is in the first position.

19. The mounting apparatus of claim 13, wherein a flange extends from each of the first side plate and the second side plate, two stopping tabs extend towards each other from each flange, and the two stopping tabs are configured to abut the electronic device, for preventing the electronic device from sliding along a second direction opposite to the first direction.

20. The mounting apparatus of claim 19, wherein a restricting portion is located on the bottom plate and opposite to the blocking member, and the restricting portion is configured to engage with the electronic device, for preventing the electronic device from moving along a third direction perpendicular to the first direction and the second direction.
